(19) United States
(12) Patent Application Publication
(10) Pub. No.: US 2017/0018654 A1
(43) Pub. Date: Jan. 19, 2017

(54) THIN-FILM TRANSISTOR AND MANUFACTURING METHOD THEREOF

(71) Applicant: NATIONAL SUN YAT-SEN UNIVERSITY, Kaohsiung City (TW)

(72) Inventors: TING-CHANG CHANG, KAOHSIUNG CITY (TW); HUA-MAO CHEN, KAOHSIUNG CITY (TW); MING-YEN TSAI, KAOHSIUNG CITY (TW); MIN-CHEN CHEN, KAOHSIUNG CITY (TW)

(21) Appl. No.: 14/798,744

(22) Filed: Jul. 14, 2015

(51) Int. Cl. H01L 29/786; H01L 21/477; H01L 29/66; H01L 29/24

(52) U.S. Cl. CPC H01L 29/78681; H01L 29/78696; H01L 29/247; H01L 21/477; H01L 29/66969

(57) ABSTRACT

A thin-film transistor and a manufacturing method thereof are characterized in that: the active layer is a group IV-VI compound semiconductor film; the group IV-VI compound is one of geranium sulfide (GeS), germanium selenide (GeSe), germanium telluride (GeTe), tin selenide (SnSe), and tin telluride (SnTe) or a ternary, quaternary, or quinary compound thereof; the active layer is deposited by sputtering; and thermal annealing is performed after the active layer is deposited. The thin-film transistor has high carrier mobility and a high current on/off ratio and therefore meets the needs of high-resolution display development.

### BACKGROUND OF THE INVENTION

1. Technical Field

The present invention relates to a thin-film transistor and a manufacturing method thereof. More particularly, the present invention relates to a thin-film transistor whose active layer is a group IV-VI compound semiconductor film, and a method for manufacturing the same.

2. Description of Related Art

Thin-film transistors (TFTs) have been extensively used as active components in flat panel displays. The active layer of a thin-film transistor serves a channel in a circuit switch and is generally an amorphous silicon film or a polysilicon film. However, an amorphous silicon film, though advantageously manufacturable at low temperature, has relatively low carrier mobility, which limits the application of such films in pixel switches, and a polysilicon film, despite its higher carrier mobility, is disadvantaged by low uniformity, which has adverse effects on component properties.

Recently, with the development of 2K and 4K resolution displays, the aforesaid conventional active layer materials have been unable to meet the requirements of such high-resolution displays. It is imperative, therefore, to devise a thin-film transistor with high carrier mobility.

Taiwan Patent No. 1221341, entitled “METHOD AND MATERIAL FOR FORMING ACTIVE LAYER OF THIN-FILM TRANSISTOR”, discloses a compound doped with a dopant in order to be used as the material of the active layer of a thin-film transistor, wherein the dopant is selected from the group consisting of alkaline-earth metals, group III A elements, group IV elements, group V A elements, group VI elements, and transitional metals, and wherein the compound is one of zinc oxide (ZnO), zinc sulfide (ZnS), zinc selenide (ZnSe), cadmium selenide (CdSe), cadmium sulfide (CdS), mercury sulfide (HgS), manganese(II) sulfide (MnS), tin(II) sulfide (SnS), lead(II) sulfide (PbS), cobalt sulfide (CoS), nickel sulfide (NiS), and cadmium telluride (CdTe). Nevertheless, with the highest carrier mobility being only 5·10⁻⁴ cm²/Vs, the thin-film transistor disclosed in the '341 patent needs further improvement.

### BRIEF SUMMARY OF THE INVENTION

To produce high-carrier mobility thin-film transistors which meet the requirements of high-resolution displays, the inventor conducted extensive research and finally succeeded in developing a thin-film transistor and a manufacturing method thereof as disclosed herein. The thin-film transistor includes a substrate, a gate electrode, a gate electrode insulating layer, a source electrode, a drain electrode, and an active layer stacked together and is characterized in that the active layer is a group IV-VI compound semiconductor film, and that the group IV-VI compound is one of geranium sulfide (GeS), germanium selenide (GeSe), germanium telluride (GeTe), tin selenide (SnSe), and tin telluride (SnTe) or a ternary, quaternary, or quinary compound thereof.

Preferably, each of the gate electrode, the source electrode, and the drain electrode is a film formed by sequentially stacking titanium (Ti), aluminum (Al), and Ti.

The thin-film transistor manufacturing method is carried out by depositing a structure including a gate electrode, a gate electrode insulating layer, a source electrode, a drain electrode, and an active layer on a substrate and is characterized in that the active layer is deposited by sputtering; that the active layer is a group IV-VI compound semiconductor film; that the group IV-VI compound is one of GeS, GeSe, GeTe, SnSe, and SnTe or a ternary, quaternary, or quinary compound thereof; and that thermal annealing is performed after the active layer is deposited.

Preferably, each of the gate electrode deposited, the source electrode deposited, and the drain electrode deposited is a film formed by sequentially stacking Ti, Al, and Ti.

Preferably, the active layer deposited is a GeTe film, and the GeTe film is deposited by sputtering under the sputtering conditions of a 10 to 35-sccm (standard cubic centimeters per minute) argon flow, a 100 to 300-W sputtering power, and a 500 to 3000-second deposition time.

The present invention has the following advantageous effects:

1. The group IV-VI compound semiconductor film is used as the active layer of the thin-film transistor such that high carrier mobility is achieved. When the active layer is formed by sputter deposition of a GeTe film and subjecting the deposited GeTe film to thermal annealing, the resulting carrier mobility reaches 96.2 cm²/Vs, which is far higher than those of the conventional thin-film transistors. In addition, the thin-film transistor has a subthreshold swing of 0.182 V/dec and a high current on/off ratio.

2. As the active layer of the thin-film transistor is formed by sputter deposition of a group IV-VI compound semiconductor film and therefore has an amorphous structure, the low uniformity problem associated with a polycrystalline active layer is avoided.

3. Not only is the active layer of the thin-film transistor formed by sputter deposition, but also the films in the other layers can be so formed to be in line with the current trend of industrial production. Accordingly, the thin-film transistor can be manufactured in large areas and large sizes.

### BRIEF DESCRIPTION OF THE SEVERAL VIEWS OF THE DRAWINGS

FIG. 1A is a schematic structural diagram showing the coplanar structure of the thin-film transistor in an embodiment of the present invention;

FIG. 1B is a schematic structural diagram showing the inverted coplanar structure of the thin-film transistor in an embodiment of the present invention;

FIG. 1C is a schematic structural diagram showing the staggered structure of the thin-film transistor in an embodiment of the present invention;

FIG. 1D is a schematic structural diagram showing the inverted staggered structure of the thin-film transistor in an embodiment of the present invention;

FIG. 2A schematically shows the first step of the thin-film transistor manufacturing method in an embodiment of the present invention, wherein the thin-film transistor to be manufactured has an inverted coplanar structure by way of example;

FIG. 2B schematically shows the step following that depicted in FIG. 2A;

FIG. 2C schematically shows the step following that depicted in FIG. 2B;

FIG. 2D schematically shows the step following that depicted in FIG. 2C;

FIG. 3 shows the electrical characteristic curve of an inverted coplanar structured thin-film transistor whose active layer is an ITZO film; and

FIG. 4 shows the electrical characteristic curve of an inverted coplanar structured thin-film transistor whose active layer is a GeTe film.

### DETAILED DESCRIPTION OF THE INVENTION

The present invention provides a thin-film transistor and a manufacturing method thereof which incorporate the foregoing technical features and whose major effects are detailed below.

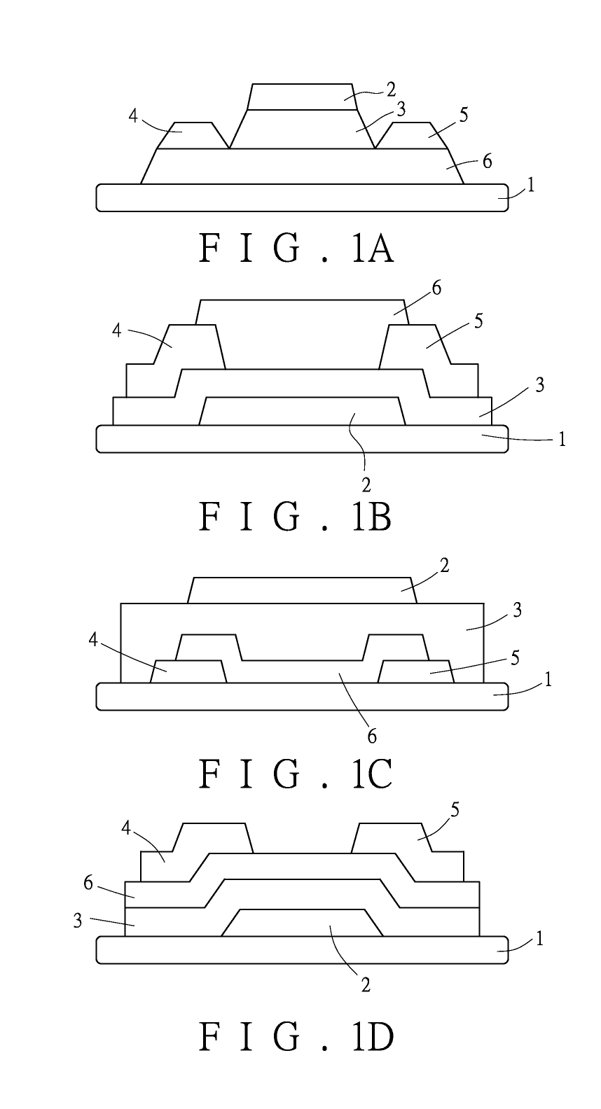

FIG. 1A to FIG. 1D show the thin-film transistors in four different embodiments of the present invention, wherein the thin-film transistors have a coplanar structure, an inverted coplanar structure, a staggered structure, and an inverted staggered structure respectively. All the four structures are well known in the art. Each of these thin-film transistors includes a substrate 1, a gate electrode 2, a gate electrode insulating layer 3, a source electrode 4, a drain electrode 5, and an active layer 6 stacked together, wherein the active layer is a group IV-VI compound semiconductor film. The group IV-VI compound can be any one of the following five compounds and their ternary, quaternary, or quinary compounds: GeS, GeSe, GeTe, SnSe, and SnTe. Each of the gate electrode 2, the source electrode 4, and the drain electrode 5 is a film formed by sequentially stacking Ti, Al, and Ti but is not limited to this construction. For example, the gate electrode 2, the source electrode 4, and the drain electrode 5 may include films of other conductors such as indium tin oxide (ITO), chromium (Cr), aluminum (Al), molybdenum (Mo), gold (Au), platinum (Pt), and mercury (Ag). The gate electrode insulating layer 3 is made of silicon dioxide (SiO₂), and yet the present invention imposes no limitations on the material of this layer.

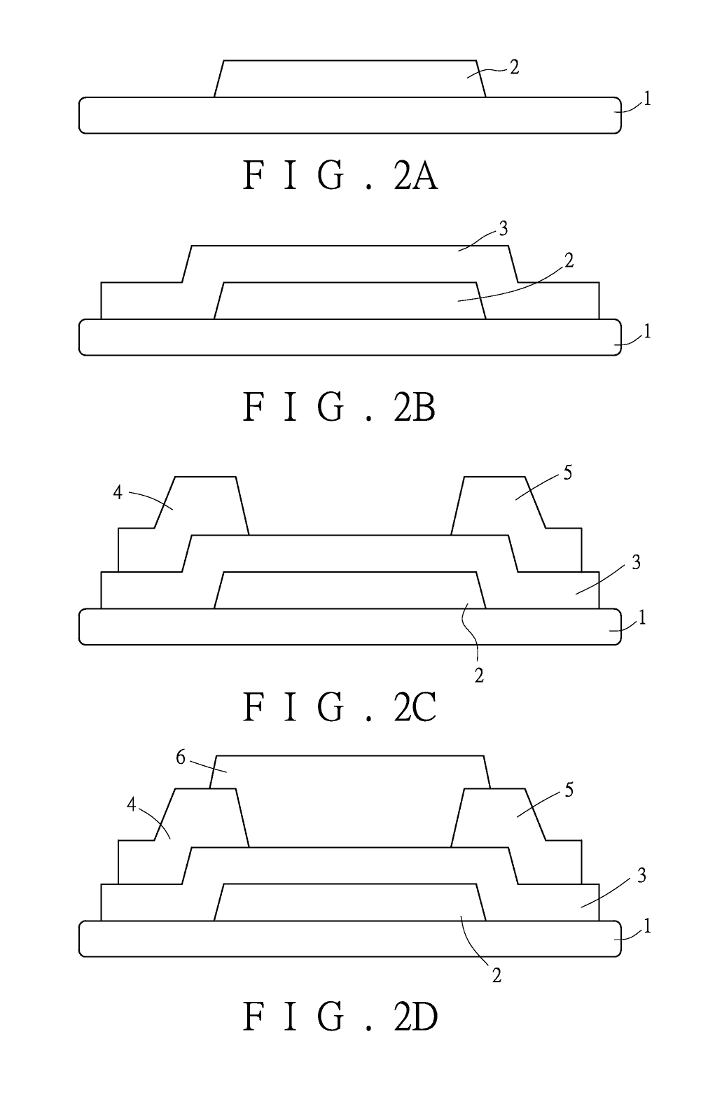

FIG. 2A to FIG. 2D illustrate the method for manufacturing a thin-film transistor according to an embodiment of the present invention, wherein the thin-film transistor to be manufactured has an inverted coplanar structure by way of example. To begin with, referring to FIG. 2A, the substrate 1 is provided, and a first electrode layer is deposited on the substrate 1 (by sputtering for example) and then patterned to form the gate electrode 2. The substrate 1 can be a glass substrate or a flexible plastic substrate. The first electrode layer is a film formed by sequentially stacking Ti, Al, and Ti but is not limited to this construction. The first electrode layer may be a film formed of other conductors such as ITO, Cr, Al, Mo, Au, Pt, and Ag. In FIG. 2B, an insulating layer serving as the gate electrode insulating layer 3 is deposited on the patterned gate electrode 2 by sputtering for example. The gate electrode insulating layer 3 is made of SiO₂ but is not necessarily so. In FIG. 2C, a second electrode layer is deposited on the gate electrode insulating layer 3 by sputtering for example and then patterned to form the source electrode 4 and the drain electrode 5. The second electrode layer is a film formed by sequentially stacking Ti, Al, and Ti but is not limited to this construction. The second electrode layer may be a film formed of other conductors such as ITO, Cr, Al, Mo, Au, Pt, and Ag. In FIG. 2D, a group IV-VI compound semiconductor film is deposited by sputtering for example and then patterned to form the active layer 6 of the thin-film transistor. The group IV-VI compound is one of GeS, GeSe, GeTe, SnSe, and SnTe or a ternary, quaternary, or quinary compound of any of the five compounds. Preferably, the group IV-VI compound semiconductor film is sputter-deposited under the sputtering conditions of an argon flow of 10 to 35 standard cubic centimeters per minute (sccm), a sputtering power of 100 to 300 W, and a deposition time of 500 to 3000 seconds. Lastly, thermal annealing is performed to enhance the film quality and electrical properties of the active layer 6.

It should be pointed out that the group VI elements in the periodic table have larger atomic orbitals, more significant electron cloud overlap, and hence higher electron transfer speed as the atomic number increases. In a conventional metal oxide, in which the oxygen atom(s) are of the group VI and have the smallest atomic number of all the group VI elements, the bond between the oxygen atom(s) and the metal is relatively weak and may break such that an oxygen vacancy (or oxygen vacancies) and the corresponding free electrons are formed. As a result, the semiconductor transfer mechanism of the metal oxide is controlled by the oxygen vacancy or vacancies. In other words, electrical conduction of the metal oxide relies mainly on the oxygen vacancy or vacancies. Since the oxygen vacancy or vacancies do not conduct electricity as easily as the free electrons in the same block, an increase in carrier mobility is difficult to achieve. On the other hand, the other group VI elements such as sulfur (S), selenium (Se), and tellurium (Te) have more significant electron cloud overlap and can hence form stronger bond with metal as they increase in atomic number. Therefore, a semiconductor formed of a metal and a group VI element such as S, Se, or Te has a transfer mechanism in which conduction is carried out essentially through electrons in a lattice arrayed block and which leads to high carrier mobility.

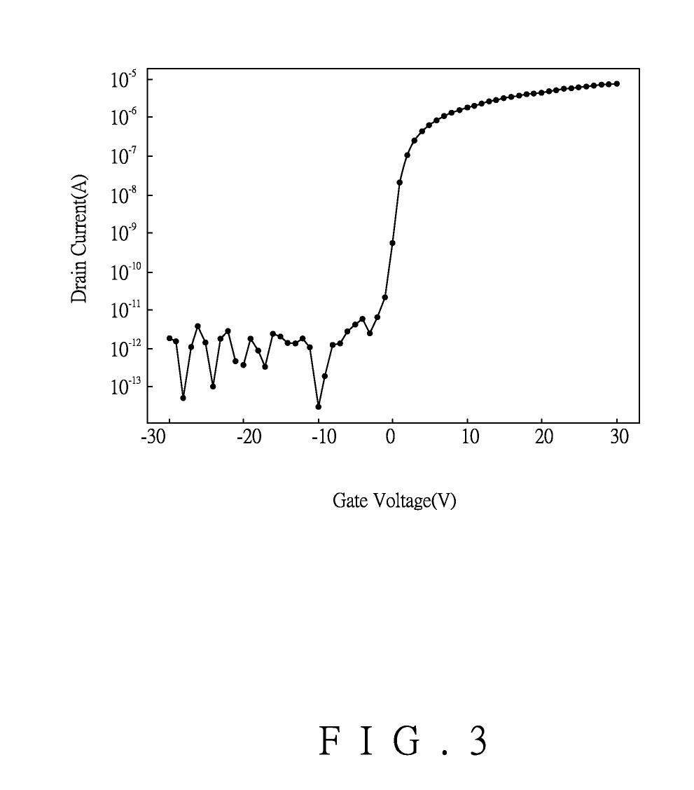

In a comparison example, a conventional metal oxide such as indium tin zinc oxide (ITZO) is used to form the active layer of a thin-film transistor. More specifically, the ITZO active layer is sputter-deposited under the sputtering conditions of a 50-W sputtering power, a 30-sccm argon flow, and a 1-sccm oxygen flow to form a 20 nm-thick film. By testing the resulting thin-film transistor, the electrical characteristic curve in FIG. 3 is obtained, in which the linear region can be expressed by the equation

$$gm = {C}_{ox} \cdot μ \cdot \frac{W}{L} {V}_{d} .$$

With gm=Id/Vg, the maximum value of gm is obtained by differentiating the drain current in FIG. 3 with respect to gate voltage. By substituting the known values of W, L, V_{d}, and Cₒₓ into the equation, carrier mobility (μ) is determined as 9.8 cm²/Vs.

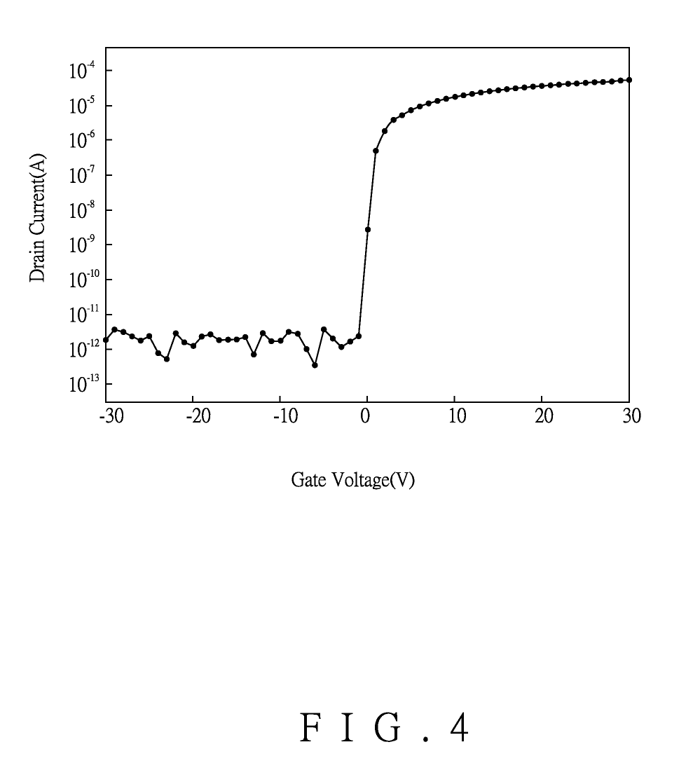

By contrast, in an embodiment of the present invention, a GeTe film is used as the active layer of a thin-film transistor of the inverted coplanar structure. More specifically, the GeTe film is sputter-deposited under the sputtering conditions of a 30-sccm argon flow, a 100-W sputtering power, and a 2000-second deposition time. Then, the GeTe film is subjected to thermal annealing conducted in an oxygen environment at 220° C. for 30 minutes until the thin-film transistor is formed. FIG. 4 shows the electrical characteristic curve obtained from test results of the thin-film transistor. By substituting the extracted drain current of 10⁻⁹ A and the corresponding gate voltage of 10⁻¹¹ V into the subthreshold swing (S.S.) equation

$$S . S . = {( \frac{\partial log ( {I}_{drain} )}{\partial {V}_{g}} )}^{- 1} ,$$

a subthreshold swing (S.S.) of 0.182 V/dec is obtained, from which it can be inferred that the transistor has a high current on/off ratio. Furthermore, based on the equation

$$gm = {C}_{ox} \cdot μ \cdot \frac{W}{L} {V}_{d}$$

of the linear region of the electrical characteristic curve in FIG. 4, the carrier mobility of the thin-film transistor is calculated as 96.2 cm²/Vs, which is far higher than that of the conventional thin-film transistor in the comparison example whose active layer is formed of ITZO.

The description of the foregoing embodiments should be able to enable a person of ordinary skill in the art to fully understand the operation, use, and effects of the present invention. The embodiments, however, are only some preferred ones of the present invention and are not intended to be restrictive of the scope of the present invention. All simple equivalent changes and modifications made according to the appended claims and the present specification should fall within the scope of the present invention.

1. A thin-film transistor, comprising a substrate, a gate electrode, a gate electrode insulating layer, a source electrode, a drain electrode, and an active layer stacked together, the thin-film transistor being characterized in that: the active layer is a group IV-VI compound semiconductor film, and said group IV-VI compound is one of geranium sulfide (GeS), germanium selenide (GeSe), germanium telluride (GeTe), tin selenide (SnSe), and tin telluride (SnTe) or a ternary, quaternary, or quinary compound thereof.

2. The thin-film transistor of claim 1, wherein each of the gate electrode, the source electrode, and the drain electrode is a film formed by sequentially stacking titanium (Ti), aluminum (Al), and Ti.

3. A method for manufacturing a thin-film transistor, comprising:
depositing on a substrate a structure including a gate electrode, a gate electrode insulating layer, a source electrode, a drain electrode;
depositing an active layer on said structure, the active layer being formed by a group IV-VI compound and being deposited by sputtering in an atmosphere devoid of oxygen, wherein said group IV-VI compound is one of germanium sulfide (GeS), germanium selenide (GeSe), germanium telluride (GeTe), tin selenide (SnSe), and tin telluride (SnTe) or a ternary, quaternary, or quinary compound thereof; and
performing thermal annealing after the active layer is deposited.

4. The method of claim 3, wherein each of the gate electrode deposited, the source electrode deposited, and the drain electrode deposited is a film formed by sequentially stacking titanium (Ti), aluminum (Al), and Ti.

5. The method of claim 3, wherein the active layer deposited is a GeTe film, and the GeTe film is deposited by sputtering under sputtering conditions of an argon flow of 10 to 35 standard cubic centimeters per minute (sccm), a sputtering power of 100 to 300 W, and a deposition time of 500 to 3000 seconds.
